(19) United States
(12) Patent Application Publication
(10) Pub. No.: US 2002/0198670 A1
(43) Pub. Date: Dec. 26, 2002

(54) Electromagnetic simulation algorithm, in particular for an electromagnetic antenna performances

(76) Inventors: Snorre Harald Christiansen, Paris (FR); Francois Bereux, Bures S/ Yvette (FR); Jean-Claude Nedelec, Igny (FR); Jean-Paul Martinaud, Leuville S/Orge (FR)

Correspondence Address: OBLON SPIVAK MCCLELLAND MAIER & NEUSTADT PC, FOURTH FLOOR, 1755 JEFFERSON DAVIS HIGHWAY, ARLINGTON, VA, 22202, US

(21) Appl. No.: 10/049,291

(22) PCT Filed: Jun. 1, 2001
(86) PCT No.: PCT/FR01/01715

(30) Foreign Application Priority Data
Jun. 9, 2000 (FR) 00/07456

(51) Int. Cl. G06F 19/00; G01R 25/00; G01R 27/00

(52) U.S. Cl. 702/65

(57) ABSTRACT

The present invention pertains to an electromagnetic simulation algorithm, which makes it possible to compute the electromagnetic wave scattered by a conductor in a monofrequency situation.

To this end, the invention relates to an electromagnetic simulation algorithm based an iterative solution of a system of integral equations comprising a preconditioner. This preconditioner arises in particular from adapting Calderon's formulae to the boundary integral equations of electromagnetism, also known as the Electric Field Integral Equation (EFIE). Use is also made of an original representation of the residual of the computations during each iteration. This representation, as well as a projection and a composition, are involved in the expression of said preconditioner.

It applies in particular to the simulation tools used during the design of reception or transmission antennas such as cellphone antennas, anti-collision radar antennas, those of electronic counter measures (ECM) systems, of monitoring or tracking radars, or satellite antennas. The invention also applies to the computation of radar cross sections (RCS) of objects whose geometrical properties are known.

The present invention pertains to an electromagnetic simulation algorithm, in particular for the performance of an antenna, which makes it possible to compute the electromagnetic wave scattered by a conductor in a monofrequency situation. It applies in particular to the simulation tools used during the design of reception or transmission antennas such as cellphone antennas, anti-collision radar antennas, those of electronic counter measures (ECM) systems, of monitoring or tracking radars, or satellite antennas. The invention also applies to the computation of radar cross sections (RCS) of objects whose geometrical properties are known.

Antenna simulations are used to limit the number of mock-ups and prototypes during the design of said antennas. These simulations make it possible in particular to compute the far-field radiation pattern of the antennas and to adapt the antennas in transmission or in reception, in the present or otherwise of a surrounding structure. As input data they use a mesh of the antenna whose performance one wishes to evaluate, as well as the characteristics of the electromagnetic excitation to which it is subject. The invention is not limited to the simulations of antennas. It applies also for example to the computations of RCSs of targets. The application of the invention within the antenna simulations, during reception, will now be described by way of illustration.

Two main methods can be distinguished within the simulations commonly employed. A first method is based on computation by finite differences, also known as the volume finite element method. According to this method, a mesh of a volume surrounding the antenna is used. A drawback of this method is that the mesh is necessarily bounded, whereas one is interested in the radiation pattern at infinity. A compromise must then be made between the dimension of the meshed volume, that is to say the accuracy of computation, and the computation time. To alleviate this drawback, a second method is used, based on integral equations within the frequency domain. According to this method, a surface mesh of the antenna only is used. The radiation pattern at infinity is computed directly from electric and magnetic currents on the surface of the antenna.

Certain known techniques using integral equations computed the electric and magnetic currents (from which the field pattern radiated at infinity is deduced) by virtue of a factorization of a matrix. This matrix is known as the interaction matrix or else the impedance matrix. This factorization allows direct computation, that is to say noniterative computation, of the surface currents. A drawback of these techniques is that the computation time is long. If N denotes the number of points involved in meshing the antenna (also termed surface triangulation), the computation time according to these techniques varies as N³. Now, the number of points N is itself related to the wavelength (and consequently the frequency) of the wave radiated by the antenna. Let us assume that a simulation is carried out at 10 GHz, by using N points in the mesh of the antenna, and that the computation time is τ. To transpose this simulation to 20 GHz, it will be necessary to use a mesh comprising 4×N points, and this will represent a computation time of the order of 4³×τ. A computation time problem arises also when one seeks to simulate complex antenna geometries, such as small-arrays. This makes these techniques unusable in particular in design tools which require a restricted computation time so as to allow the designers to carry out several tests.

Other known techniques using integral equations make it possible to reduce the computation time by virtue of an iterative solution method. If IT denotes the number of iterations, the computation time according to these techniques varies as It×N². One problem with these techniques is that nothing guarantees the convergence of the computations. Stated otherwise, antenna shapes exist for which the radiated field pattern cannot be computed with these techniques.

An aim of the invention is to alleviate the aforesaid drawbacks, and in particular to restrict the computation times.

To this end, the invention relates to an algorithm for simulating the performance of an antenna, based on iteratively solving a system of integral equations comprising a preconditioner. This preconditioner arises in particular from adapting Calderon's formulae to the boundary integral equations of electromagnetism. In particular, in the case of a completely metal antenna, a preconditioner is proposed for the equation known as the “Electric Field Integral Equation” (EFIE). Use is also made of an original representation of the residual of the computations during each iteration. This representation, as well as a projection and a composition, are involved in the expression of said preconditioner.

The invention has the following main advantages:

it converges rapidly;

it makes it possible to simulate arbitrary geometries and any excitations;

its conditioning is independent of the fineness of the mesh;

it accommodates algorithms based on the computation of an impedance matrix, by reusing said impedance matrix;

it makes it possible to deal with antennas comprising, in addition to metal, dielectric materials.

Other characteristics and advantages of the invention will become more clearly apparent in the description which follows and in the appended figures which represent:

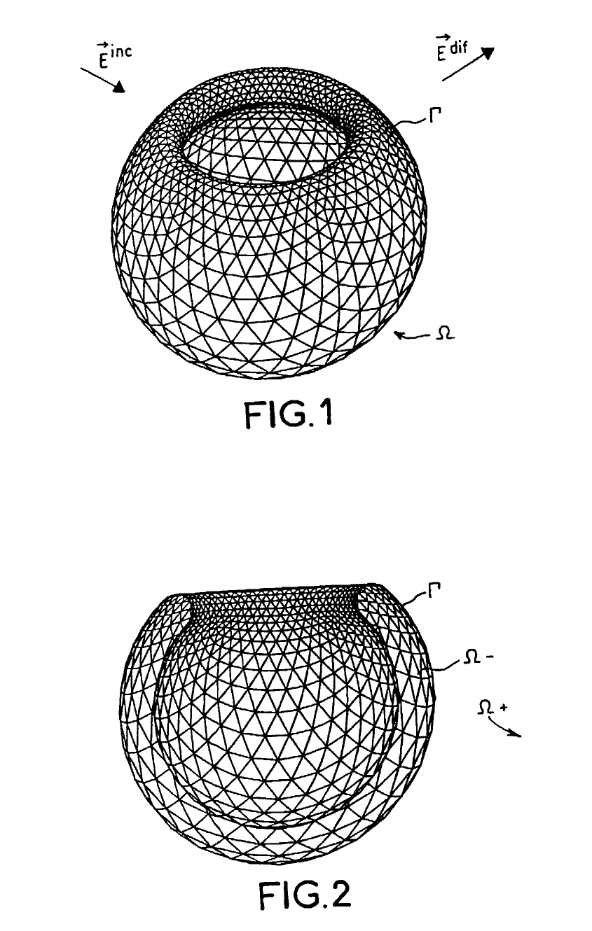

FIG. 1, a mesh of an antenna;

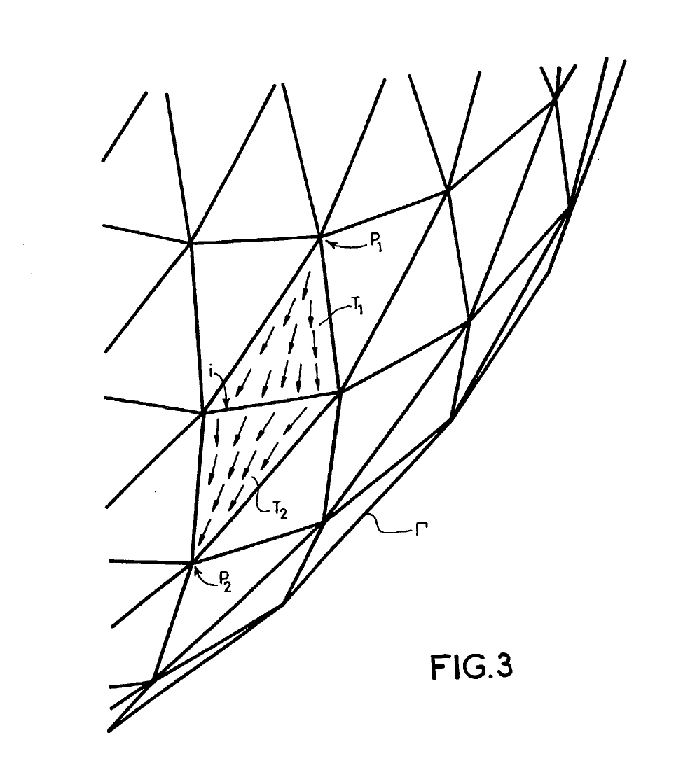

FIG. 2, a sectional view of the mesh of FIG. 1;

FIG. 3, a detail of the mesh of FIG. 1, in which a vector field is represented;

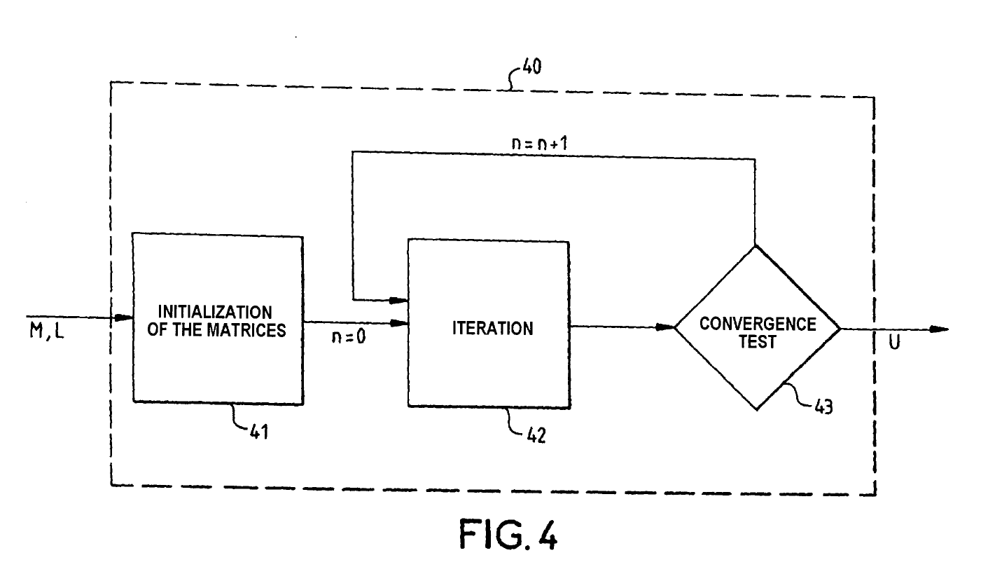

FIG. 4, a functional diagram of an iterative algorithm;

FIG. 5, a trianglewise constant basis function over a mesh;

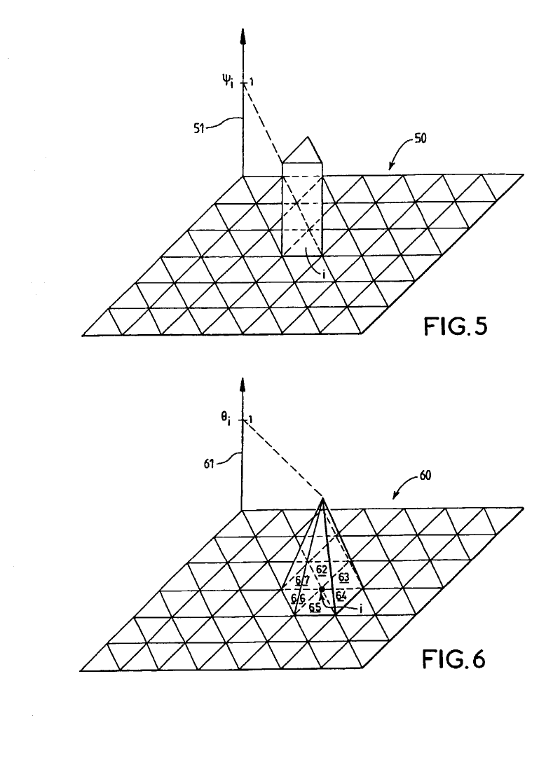

FIG. 6, a trianglewise affine and continuous basis function over a mesh;

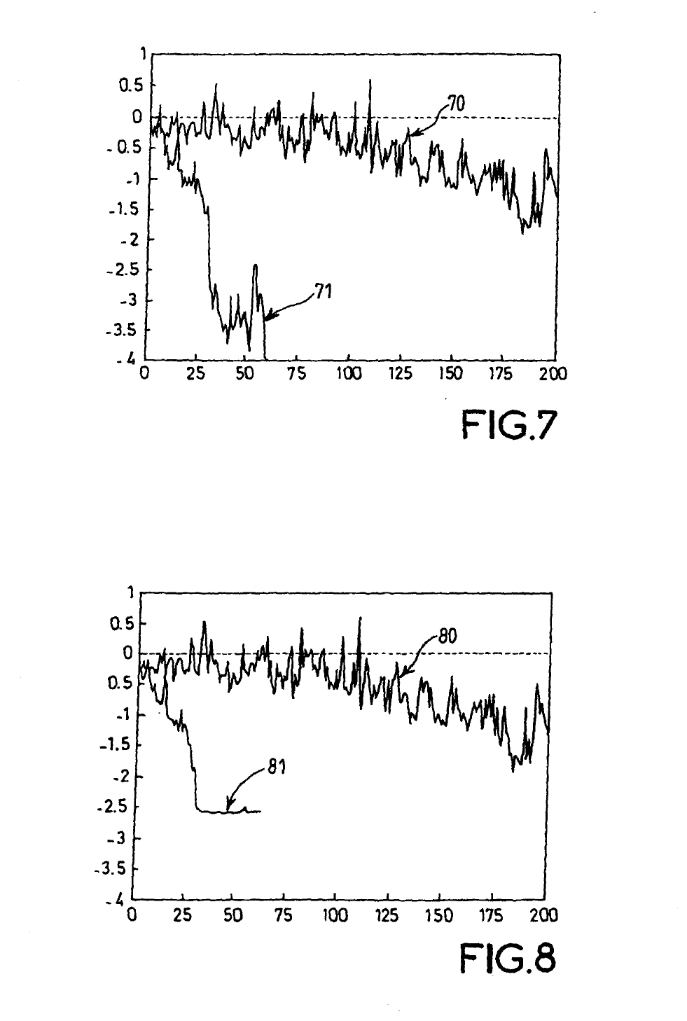

FIGS. 7 and 8, two illustrations of the performance of the algorithm according to the invention as compared with known techniques.

Reference will now be made to FIGS. 1 and 2 which represent an exemplary antenna shape for which one seeks to determine the scattered field when the antenna is illuminated by an incident wave. Stated otherwise, one seeks to simulate an antenna during reception. The antenna taken in this example is a spherical cavity with aperture half-angle π/4. The inside radius is ⅞, the outside radius is 9/8 (arbitrary unit of length). The surface of the antenna is denoted _{\vec{x}}_{₁}_{ⁱ}. This surface Γ is meshed with triangles. The surface Γ is assumed to be that of a perfect conductor (the antenna) Ω− immersed in a vacuum Ω+.

In this example, the incident electromagnetic wave which illuminates the antenna is a monofrequency plane wave. This incident electromagnetic wave, of known wavenumber k^{inc}, is represented by two vector fields denoted \vec{E}^{inc} and \vec{H}^{inc} corresponding respectively to the electric field and to the electric field and to the magnetic field. Of course, the invention does not apply only to plane waves. It is possible to substitute this incident wave with the field emitted by a radiating dipole for example (transmitter mode of the antenna).

One seeks to determine the electromagnetic wave scattered by the antenna at infinity, that is to say the far-field radiation pattern. This scattered electromagnetic wave is represented by two vector fields denoted \vec{E}^{dif} and \vec{H}^{dif} corresponding respectively to the electric field and to the magnetic field.

The electromagnetic field radiated at any point in space can be computed from the field of current flowing around the surface of said antenna, also referred to as electric and magnetic surface currents. The asymptotic expression at infinity for the electromagnetic field radiated is the radiation pattern which one seeks to determine. This computation, well known in electromagnetism, is recalled in the document “Integral Equation Methods in Scattering Theory” by D. Colton and R. Kress—John Wiley & Sons, New York, 1983.

The electromagnetic field satisfies Maxwell's equations within the vacuum Ω+ which may be written:

\vec{curl}(\vec{E})=iωμ\vec{H} (1)

\vec{curl}(\vec{H})=−iω∈\vec{E} (2)

The terms used in these equations represent:

\vec{curl} the curl operator

\vec{E}=\vec{E}^{inc}+\vec{E}^{dif} the total electric field in complex notation:

\vec{H}=\vec{H}^{inc}+\vec{H}^{dif} the total magnetic field in complex notation:

i=\sqrt{−1};

ω the angular frequency of the electromagnetic wave;

μ the magnetic permeability;

∈ the electric permitivity.

It is recalled that the wavenumber is related to the angular frequency simply by the following relation:

k=ω\sqrt{μ∈} (3)

The electric field of the scattered electromagnetic wave \vec{E}^{dif} is expressed at any point B of Ω+ on the basis of the surface currents denoted \vec{u} by the following relations:

$$\begin{matrix}{\vec{E}}^{dif} ( B ) = k {\int }_{A ∈ Γ} {G}_{k} ( A , B ) \vec{u} ( A ) ⅆ {S}_{A} + \frac{1}{k} {\vec{grad}}_{B} ( {\int }_{A ∈ Γ} {G}_{k} ( A , B ) {div}_{A} ( \vec{u} ) ⅆ {S}_{A} ) & ( 4 ) \\ {G}_{k} ( A , B ) = \frac{1}{4 π} \frac{{e}^{lk AB}}{AB} & ( 5 )\end{matrix}$$

The terms of the relations (4) and (5) represent:

div_{A} (\vec{u}) the divergence taken at a point A of the vector field \vec{u};

\vec{grad}_{B} the gradient taken at a point B;

dS_{A} a differential surface element;

Gₖ the standard Green's function;

AB the distance between the points A and B;

k the norm of the wavenumber defined by relation (3).

A person skilled in the art will be able to investigate other technical elements relating to this computation in the abovementioned document insofar as the latter forms an integral part of the description.

The computation of the surface currents, that is to say of the vector field \vec{u}, is determined from the following variational equation:

∀\vec{v}m(\vec{u},\vec{v})=l(\vec{v}) (6)

in which

$$\begin{matrix}m ( \vec{u} , \vec{v} ) = k \int {\int }_{{A ∈ Γ}_{B ∈ Γ}} {G}_{k} ( A , B ) \vec{u} ( A ) \cdot \vec{v} ( B ) ⅆ {S}_{A} ⅆ {S}_{B} - \frac{1}{k} \int {\int }_{{A ∈ Γ}_{B ∈ Γ}} {G}_{k} ( A , B ) {div}_{A} ( \vec{u} ) {div}_{B} ( \vec{v} ) ⅆ {S}_{A} ⅆ {S}_{B} \\ and & ( 7 ) \\ I ( \vec{v} ) = - {\int }_{A ∈ Γ} {\vec{E}}^{inc} ( A ) \cdot \vec{v} ( A ) ⅆ {S}_{A} & ( 8 )\end{matrix}$$

This variational equation (6) is known as the boundary integral equation of electromagnetism, or else the “Electric Field Integral Equation” (EFIE).

In order to solve this variational equation (6) in a numerical antenna simulation, we must approximate the solution \vec{u} in a space of finite dimension, the so-called discretization space. This space contains vector fields which represent surface currents. The dimension this space is the number of components required to fully describe said vector field, at every point of the surface Γ. This surface being meshed, the number of components serving to describe \vec{u} will depend in particular on the number of points of the mesh N, as well as the nature of the basis functions serving to described the vector field (for example, linear functions or functions of degree 2). In the subsequent description, we shall by way of illustration take the Raviart-Thomas space of lowest degree over the mesh of Γ. This discretization space, which represents surface currents, is denoted Dh. The symbol h represents the characteristic length of the mesh, or else the accuracy of the meshing. Specifically, the dimension number of this space Dh depends on the number of points N of the mesh, which itself depends on the accuracy h of the meshing.

Reference is now made to FIG. 3 to describe a basis of the space Dh. In this basis, the surface current field \vec{u} is represented by the coefficients of a vector denoted U.

The basis of the space of surface currents contains elements denoted by \vec{φ}ᵢ where i is an integer index associated with an edge of the mesh of the surface Γ. These elements are vector fields defined over the mesh of the surface Γ. The vector field \vec{φ}ᵢ, represented by arrows in FIG. 3, has a support bounded to two triangles T₁ and T₂ of the mesh. These triangles T₁ and T₂ share the edge of index i and of length lᵢ. This edge is oriented by a vector of unit norm denoted by \vec{y}ᵢ. P₁ denotes the vertex of the triangle T₁ not contained on the edge i; P₂ denotes the vertex of the triangle T₁ not contained on the edge i; P₂ denotes the vertex of the triangle T₂ not contained on the edge i. S₁ and S₂ denote the surface areas of the triangles T₁ and T₂. Let \vec{z}₂ and \vec{z}₂ be the vectors with unit norm, having a direction normal to the surface of the triangles T₁ and T₂, and oriented from the interior Ω− to the exterior Ω+. We define the vectors \vec{x}₁ⁱ and \vec{x}₂ⁱ to be the vectors with unit norms such that the triple (\vec{x}₁ⁱ,\vec{y}ᵢ,\vec{z}₁) and the triple (\vec{x}₂ⁱ,\vec{y}ᵢ,\vec{z}₂) are right-handed trihedral. We define the vector field \vec{φ}ᵢ, for any point A belonging to the surface Γ with the following relations:

$$\begin{matrix}• if A ∈ {T}_{1} , {\vec{ϕ}}_{i} ( A ) = \pm \frac{{l}_{i}}{{S}_{1}} \vec{{P}_{1} A} with {\vec{ϕ}}_{i} ( A ) \cdot {\vec{x}}_{1}^{i} > 0 ; & ( 9 ) \\ • if A ∈ {T}_{2} , {\vec{ϕ}}_{i} ( A ) = \pm \frac{{l}_{i}}{{S}_{2}} \vec{{P}_{2} A} with {\vec{ϕ}}_{i} ( A ) \cdot {\vec{x}}_{2}^{i} > 0 ; & ( 10 ) \\ • otherwise , {\vec{ϕ}}_{i} ( A ) = \overline{0} . & ( 11 )\end{matrix}$$

otherwise, \vec{φ}ᵢ(A)=\vec{0}. (11)

Such a basis of the space of currents is known as the usual basis of the Raviart-Thomas space—or else Rao-Wilton-Glisson elementary currents. A person skilled in the art will be able to investigate other technical elements in “Electromagnetic scattering by surfaces of arbitrary shape” by S. S. M. Rao, D. R. Wilton and A. W. Glisson—IEEE Trans. Ant. Prop. AP-30, pp. 409-418, 1982—insofar as this documents forms an integral part of the description.

Uᵢ denotes the coefficients of the vector U. The vector field \vec{u}(A) used in relation (4) decomposes over the usual basis of the Raviart-Thomas space in the following manner:

$$\vec{u} ( A ) = {\sum }_{i} {U}_{i} {\vec{ϕ}}_{i} ( A ) \qquad ( 12 )$$

We now transpose relations (6), (7) and (8) into matrix notation by using the basis (\vec{φ}ᵢ) described above. The variational equation (6) can be written in the form of the following system of linear equations:

MU=L (13)

The terms of relation (13) are as follows:

M is a known matrix, the so-called interaction matrix or impedance matrix;

L is a known vector, whose coefficients represent the incident wave, that is to say the electromagnetic excitation;

U is the vector which we seek to determine, whose coefficients represent the surface currents.

We define the coefficients Mᵢⱼ of the interaction matrix M and the coefficients Lᵢ of the vector L representing the incident wave by the following relations:

$${M}_{ij} = k \int {\int }_{{A ∈ Γ}_{B ∈ Γ}} {G}_{k} ( A , B ) ( {\vec{ϕ}}_{i} ( A ) \cdot {\vec{ϕ}}_{j} ( B ) ) ⅆ {S}_{A} ⅆ {S}_{B} - \frac{1}{k} \int {\int }_{{A ∈ Γ}_{B ∈ Γ}} {G}_{k} ( A , B ) {div}_{A} ( {\vec{ϕ}}_{i} ) {div}_{B} ( {\vec{ϕ}}_{j} ) ⅆ {S}_{A} ⅆ {S}_{B} \qquad ( 14 )$$

$${L}_{i} = {\int }_{A ∈ Γ} ( {\vec{E}}^{inc} ( A ) \cdot {\vec{ϕ}}_{i} ( A ) ) ⅆ {S}_{A} \qquad ( 15 )$$

A person skilled in the art will be able to investigate other technical elements relating to the computation of these coefficients in “Approximation par éléments finis de surface de problèmes de divergence des ondes électromagnétiques [Finite surface element approximation of electromagnetic wave diffraction problems ]” by A. Bendali—Thesis of the University of Paris VI, 1984—insofar as this document forms an integral part of the description.

Reference is now made to FIG. 4 wherein is illustrated an iterative algorithm for solving the system of linear equations (13) based on the conjugate gradient technique. It should be noted that the preconditioning technique which we illustrate in the case of the conjugate gradient algorithm applies equally well to other iterative algorithms. Mention may be made in particular of the Generalized Minimum Residual (GMRES) algorithm, Bi Conjugate gradient (BiCG) algorithm, Quasi-Minimal Residual (QMR) algorithm and the BiConjugate Gradient Stabilized (Bi-CGSTAB) algorithm. A person skilled in the art will be able to investigate other technical elements regarding iterative methods in “Templates for the Solution of Linear Systems: Building Blocks for Iterative Methods” by R. Barrett, M. Berry, T. F. Chan, J. Demmel, J. Donate, J. Dongarra, V. Elijkhout, R. Pozi, C. Romine and H. Van der Vorst—SIAM (1994), Philadelphia, Pa.—insofar as this document forms an integral part of the description.

FIG. 4 illustrates an algorithm 40 which takes as input the matrix M and vector L of equation (13) and gives as output the vector U. A person skilled in the art will be able to investigate other technical elements relating to the solving of systems of linear equations in “Iterative Methods for Linear and Nonlinear Equations” by C. T. Kelley—SIAM Frontiers in Applied Mathematics, Philadelphia, 1995—insofar as this document forms an integral part of the description.

A first initialization step 41 makes it possible to initialize four series of vectors denoted U[n], R[n], S[n] and P[n] where N is an integer. The first series U[n] is an approximate solution which converges to the sought-after solution U. The second series R[n], known as the residual, converges to the zero vector. The third series S[n], dubbed the preconditioned residual, also converges to the zero vector. The last series P[n] is known as the search direction. The first values of these series are defined by the following relations:

U[0]=0 (16)

R[0]=L−MU[0] (17)

S[0]=ZR[0] (18)

P[0]=S[0] (19)

Relation (16) is used by default when no approximate solution is known. A variant of this relation consists in taking U[0] to be the result of a surface current computation carried out for one and the same antenna but at another frequency.

The term Z in relation (18) is a matrix. This matrix is a preconditioner for the matrix M according to the invention. It is recalled that a preconditioner of M is a matrix approximating the inverse of M. According to one variant, the preconditioner Z can be replaced by the identity. Stated otherwise, S[0] can be initialized with R[0].

A second iteration step 42 makes it possible to compute the values of the aforesaid series at a rank n+1 from the terms of rank n. This iteration step uses the following relations:

U[n+1]=U[n]+αP[n] (20)

R[n+1]=R[n]−αMP[n] (21)

S[n+1]=ZR[n+1] (22)

$$P [ n + 1 ] = S [ n + 1 ] + \frac{⟨ R [ n + 1 ] , S [ n + 1 ] ⟩}{⟨ R [ n ] , S [ n ] ⟩} P [ n ] \qquad ( 23 )$$

with

$$α = \frac{⟨ R [ n ] , S [ n ] ⟩}{⟨ MP [ n ] , P [ n ] ⟩} \qquad ( 24 )$$

where <,> represents the complex scalar product in matrix notation.

A last step 43 carries out a convergence test. This test can be expressed for example by the following inequality:

$$\frac{‖ R [ n ] ‖}{‖ R [ o ] ‖} \leq η \qquad ( 25 )$$

where η is a predetermined threshold. Stated otherwise, the normalized preconditioned residual is compared against the a predetermined threshold η. When the inequality (25) holds, the computation is halted and we take U=U[n] as solution. In the converse case, the value of n is incremented and we return to step 42.

Of course, it is possible to use another convergence test to stop the iterations. It is for example possible to replace the inequality (25) by the following inequality:

$$\frac{‖ S [ n ] ‖}{‖ S [ o ] ‖} \leq η \qquad ( 26 )$$

The conjugate gradient algorithm in the contemporary techniques is used without a preconditioner, that is to say with the matrix Z equal to the identity.

The invention consists in using a preconditioner based on a generalization of a formula of Calderon. A person skilled in the art will be able to investigate technical elements regarding this formula of Calderon in “Mathematical Methods in Electromagnetism, Linear Theory and Applications” by M. Cessenat—World Scientific Publishing Co., page 89, 1996—insofar as this document forms an integral part of the description. This formula may be written:

JMJM+JRJR=¼I (27)

In this relation (27), M, J and R are three operators over the fields of tangent vectors, that is to say mappings which associate with a field of tangent vectors another field of tangent vectors, and I is the identity mapping. J is the operator of scalar product with the normal to the surface of the antenna, and M is the operator associated with the interaction matrix for which we seek a preconditioner. The operators M, J and R are defined formally by the following relations:

$$( \vec{u} ) ( B ) = {[ k {\int }_{A ∈ Γ} {G}_{k} ( A , B ) \vec{u} ( A ) ⅆ {S}_{A} + \frac{1}{k} \vec{{grad}_{B}} ( {\int }_{A ∈ Γ} {G}_{k} ( A , B ) {div}_{A} ( \vec{u} ) ⅆ {S}_{A} ) ]}_{t} \qquad ( 28 )$$

(J\vec{u})(B)=\vec{u}(B)ˆ \vec{z}(B) (29)

$$( \vec{u} ) ( B ) = {\int }_{A ∈ Γ} \vec{{grad}_{B}} ( {G}_{k} ( A , B ) ) ⋀ \vec{u} ( A ) ⅆ {S}_{A} \qquad ( 30 )$$

In relations (28), (29) and (30), M\vec{u}, J\vec{u}, R\vec{u} and \vec{u} are tangent vector fields. The index t in relation (28) represents the tangential component of the vector between square brackets. B is a point of the surface Γ. \vec{z}(B) is a unit vector, normal to the surface Γ at B and oriented outward.

The Applicant has found that the operator J R J R being compact, that is to say negligible, the operator 4 J M J is approximately an inverse of the operator M. Next, the preconditioner being defined to within a multiplicative constant, it is possible to eliminate constant 4. Knowing that J☆=−J, the preconditioner according to the invention is defined from J☆ M J. It is recalled that J☆ is the operator adjoint to J, that is to say the operator satisfying the following relation:

∫J☆\vec{u}·\vec{v}=∫\vec{u}·J\vec{v} (31)

The preconditioner according to the invention is a matrix formulation of the operator J☆ M J. It is in this matrix formulation that the advantage of using the operator J☆ M J rather than the operator J M J appears. Specifically, the matrix formulation Z of the operator J☆ M J is a symmetric matrix, this being essential for iterative algorithms, such as the conjugate gradient.

An exemplary preconditioner according to the invention which makes it possible to speed up the convergence of the algorithm and also to render this algorithm more stable (we always converge to the solution regardless of the initial conditions) will now be described. This preconditioner is adapted to electromagnetic problems and exploits the structure of the problem to be solved.

We firstly define spaces and their assocated bases which will serve subsequently in the description. We have already defined the basis (\vec{φ}ᵢ). The space spanned by this basis, Dh, is a space of tangent vector fields. Stated otherwise, Dh is a set of functions which with any point of Γ associate a vector tangent to the meshed surface Γ. We also define two function spaces Ch and Sh. The functions of these spaces associate a scalar value with each point of Γ.

Ch is the set of trianglewise constant functions, that is to say those whose value is constant for any point belonging to a given triangle. The basis of Ch which we use subsequently is the set of functions denoted Ψi, which equal 1 on the triangle of index i and 0 outside. Reference is made to FIG. 5 in which a basis function Ψᵢ is represented. A plain, regular mesh 50 has been represented for the sake of clarity. The values of the function Ψᵢ are represented on an axis 51, perpendicular to the mesh 50. The function Ψᵢ represented in this figure equals 1 on the triangle i and 0 outside.

Sh is the set of trianglewise affine continuous functions. These functions have a constant gradient over any given triangle. The basis of Sh which we use subsequently is the set of functions denoted θᵢ, which equal 1 at the node of index i and 0 on the other nodes. Reference is made to FIG. 6 in which a basis function θ₁ is represented. A plain, regular mesh 60 has been represented for the sake of clarity. The values of the function θᵢ are represented on an axis 61, perpendicular to the mesh 60. The function θᵢ represented in this figure trianglewise is affine and equals 1 at node i. This function has a support (non-zero values) bounded at the triangles 62, 63, 64, 65, 66, 67 which have a vertex coinciding with node i.

A person skilled in the art will be able to investigate further technical elements in “Handbook of Numerical Analysis Vol. II, Finite Elements Methods (Part 1)” by P. G. Ciarlet—Ed. J. L. Lions, North-Holland, 1991—insofar as this document forms an integral part of the description.

We shall now define matrices which will serve in the subsequent description of the preconditioner. These matrices are based on the bases defined above. They are expressed by the following relations:

$$\begin{matrix}{M1}_{ij} = {\int }_{A ∈ Γ} {\vec{ϕ}}_{i} ( A ) \cdot {\vec{ϕ}}_{j} ( A ) ⅆ {S}_{A} & ( 32 ) \\ {M2}_{ij} = {\int }_{A ∈ Γ} {ψ}_{j} ( A ) {div}_{A} ( {\vec{ϕ}}_{i} ) ⅆ {S}_{A} & ( 33 ) \\ {M3}_{ij} = {{\int (}_{A ∈ Γ}}^{} {\vec{ϕ}}_{j} ( A ) ⋀ \vec{z} ( A ) ) \cdot {\vec{ϕ}}_{i} ( A ) ⅆ {S}_{A} & ( 34 )\end{matrix}$$

where \vec{z}(A) is a vector with unit norm, normal to the surface Γ at the point A and oriented outward.

$$\begin{matrix}{M4}_{ij} = {\int }_{A ∈ Γ} {ψ}_{j} ( A ) {θ}_{i} ( A ) ⅆ {S}_{A} & ( 35 ) \\ {M5}_{ij} = {\int }_{A ∈ Γ} {θ}_{j} ( A ) {θ}_{i} ( A ) ⅆ {S}_{A} & ( 36 )\end{matrix}$$

M6ᵢⱼ=(\vec{rot}(θⱼ))_{φ}_{ᵢ} (37)

The steps which make it possible to compute the preconditioned residual from the residual in relations (18) and (22) is now described. These relations use the preconditioner Z which is now described. In the description which follows, we give a decomposition of this matrix Z into a product of matrices. The matrices involved in this product are sparse matrices or inverse sparse matrices. Thus, according to an advantageous variant of the invention, use will preferably be made of sparse matrices rather than the matrix Z directly, thereby making it possible in particular to reduce the memory used and the computation time.

We now denote by R the residual and S the preconditioned residual. R corresponds respectively to R[0] and to R[n+1] in relations (18) and (22). S corresponds respectively to S[0] and to S[n+1] in relations (18) and (22).

A first step consists in using a mixed representation. This step will be better understood with the aid of the vector notations which will then be transposed into matrix notations. The residual R corresponds to a bilinear form over the space Dh defined above. This bilinear form is denoted ρ. We represent ρ by a vector field \vec{r}1 in Dh of zero divergence and a function q1 in Ch of zero integral. The field \vec{r}1 and the function q1 are defined by the following relation for any vector field \vec{v} in Dh:

$${\int }_{A ∈ Γ} \vec{r1} ( A ) \cdot \vec{v} ( A ) ⅆ {S}_{A} + {\int }_{A ∈ Γ} q1 ( A ) {div}_{A} ( \vec{v} ) ⅆ {S}_{A} = ρ ( \vec{v} ) \qquad ( 38 )$$

The vector field \vec{r}1 having zero divergence, we can write for any function f in Ch and of zero integral:

$${\int }_{A ∈ Γ} f ( A ) {div}_{A} ( \vec{r1} ) ⅆ {S}_{A} = 0 \qquad ( 39 )$$

Subsequently, so as not to needlessly complicate the presentation, we shall not repeat that the scalar fields considered are of zero integral.

Relations (38) and (39) are transposed in matrix fashion as follows:

$$( \begin{matrix}M1 & M2 \\ {}^{t} M2 & 0\end{matrix} ) ( \begin{matrix}R1 \\ Q1\end{matrix} ) = ( \begin{matrix}R \\ 0\end{matrix} ) \qquad ( 40 )$$

In relation (40), we have used a blockwise matrix notation in which:

^{t}M2 is the matrix transposed from M2;

0 is a zero block (vector or matrix);

R1 is the matrix representation of \vec{r}1;

Q1 is the matrix representation of q1.

We recall that it is not necessary to invert the blockwise defined matrix in order to determine R1 and Q1 from R. Specifically, this matrix is a sparse matrix, that is to say one which contains many zero terms. The procedure for solving such a system is well known to a person skilled in the art. It is recalled in “Handbook of Numerical Analysis Vol. II, Mixed and hybrid methods” pp 523-640 by J. E. Roberts et J. -M. Thomas—Ed. J. L. Lions, North-Holland, 1991. This document forms an integral part of the description.

A second step consists in projecting \vec{r}1 and q1. These projections are manifested by the following relations in vector notation:

\vec{r2}=p_{Dh}(\vec{r1}ˆ \vec{z}) (41)

q2=p_{Sh}(q1) (42)

where:

^{P}_{Dh} is the projection operator in Dh;

^{P}ₛₕ is the projection operator in Sh;

\vec{z} is a unit vector, normal to Γ and oriented outward.

These projections defined by relations (41) and (42) are manifested in matrix fashion by:

$$( \begin{matrix}M1 & 0 \\ 0 & M5\end{matrix} ) ( \begin{matrix}R2 \\ Q2\end{matrix} ) = ( \begin{matrix}M3 & R1 \\ M4 & Q1\end{matrix} ) \qquad ( 43 )$$

The solution procedure for relation (43) is similar to the solution procedure for relation (40) insofar as the matrices M1 and M5 are sparse matrices. It may be noted that this solution procedure is even easier than that for relation (40) insofar as the matrices M1 and M5 are moreover symmetric, positive definite and well-conditioned. We thus determine \vec{R2} and \vec{Q2} from R1 and Q1.

A third step consists in combining \vec{r2} and q2 using the following relation:

\vec{r3}=\vec{r2}−\vec{curl}(q2) (44)

This third step is manifested in matrix fashion by:

R3=R2−M6Q2 (45)

We call J the vector mapping which results from the composition of the three steps described above. This mapping is defined by:

j(\vec{r})=\vec{r3} (46)

This relation (46) transposes in matrix notations to:

JR=R3 (47)

where J denotes the matrix corresponding to the vector mapping J, the matrix J being defined by the following product:

$$J = ( 1 - M6 ) {( \begin{matrix}M1 & 0 \\ 0 & M5\end{matrix} )}^{- 1} ( \begin{matrix}M3 & 0 \\ 0 & M4\end{matrix} ) {( \begin{matrix}M1 & M2 \\ {}^{t} M2 & 0\end{matrix} )}^{- 1} ( \begin{matrix}1 \\ 0\end{matrix} ) \qquad ( 48 )$$

It is not of course necessary to compute J directly, since the decomposition (48) into a product of sparse matrices and of inverses of sparse matrices is simpler to use. Stated otherwise, the matrix J is computed implicitly during its use.

We denote by Z the vector mapping which corresponds to the matrix of the preconditioner Z. The preconditioner Z is defined via the vector mapping J by:

z=j*o\hat{m}oj (49)

where

j* is the adjoint of j;

o is the composition operator for composing mappings;

\hat{m} is the linear mapping Dh→Dh* associated with the bilinear form m.

Relation (42) is manifested in matrix fashion by:

Z=^{t}JMJ (50)

Reference is now made to FIGS. 7 and 8 in which the performance of an algorithm with a preconditioner according to the invention is illustrated in comparison with the known techniques not using a preconditioner.

In FIG. 7, the curve 70 represents the function

$$n ↦ {log}_{10} ( \frac{‖ S [ n ] ‖}{‖ S [ 0 ] ‖} )$$

in the absence of a preconditioner. The curve 71 represents the function

$$n ↦ {log}_{10} ( \frac{‖ S [ n ] ‖}{‖ S [ 0 ] ‖} )$$

in the presence of the preconditioner described above.

In FIG. 8, the curve 80 represents the function

$$n ↦ {log}_{10} ( \frac{‖ R [ n ] ‖}{‖ R [ 0 ] ‖} )$$

in the absence of a preconditioner. The curve 81 represents the function

$$n ↦ {log}_{10} ( \frac{‖ R [ n ] ‖}{‖ R [ 0 ] ‖} )$$

in the presence of the preconditioner described above.

It is found that if a conventional convergence criterion η=10⁻⁴ is taken in relation (25), 50 iterations are sufficient with the preconditioner. With a nonpreconditioned algorithm, a sufficient accuracy is not reached in 200 iterations.

These numerical simulations have made it possible to show that the use of a preconditioner according to the invention makes it possible to speed up and to stabilize the iterative algorithms.

Of course, the invention is not limited to the example used to describe it. It is possible in particular to use other basis functions or a different mesh from those taken by way of example.

The invention generalizes to any other discretization of the space Dh. If we take a space other than the Raviart-Thomas space for Dh, then the spaces Ch and Sh are replaced respectively by:

Ch={div(\vec{u})|\vec{u}∈Dh}+1 (51)

Sh={\vec{p}|\vec{curl}(\vec{p})∈Dh} (52)

Stated otherwise,

Ch is a minimal finite element space such that the divergence of the elements of Dh lies in Ch;

Sh is a maximal finite element space such that the curl of the elements of Sh lies in Dh.

A main application of the invention is found in antenna design tools, but the invention is not limited to this application alone. The invention applies also of course to any simulation tool based on the computation of the field radiated by a conductor. Mention may be made in particular of the computation of radar cross sections (RCS) of objects whose geometrical properties are known.

It should be also be noted that the preconditioning technique described in cases of an iterative method also applies to other fast numerical methods. These fast methods are based on an iterative solution procedure, but only the terms which are useful to the matrix-vector products are computed. Thus, of the order of N×log(N) elements of the impedance matrix are computed, instead of N² elements according to the conventional iterative techniques. Stated otherwise, the impedance matrix is computed implicitly. The use of the preconditioner according to the invention in these fast methods is achieved without difficulty. These methods are beneficial in respect of objects of large size, that is to say for N large. Such is the case in particular for so-called on-structure antenna simulations. Mention may be made in particular of the Multilevel Multipole Methods (or Fast Multilevel Multipole Methods) (FMM) and the Adaptive Integral Methods (AIM). A person skilled in the art will be able to investigate technical elements regarding:

fast methods in general in “Fast Solution Methods In Electromagnetics” by W. C. Chew, J. -M. Jin, C. -C. Lu, E. Michielssen, J. M. Song—IEEE Trans. on Antennas and Propagation, 45(3):533-543, March 1997;

Multilevel Multipole Methods in “Multilevel Fast Multipole Algorithm For Electromagnetic Scattering By Large Complex Objects” by J. M. Song, C. -C. Lu, W. C. Chew, S. W. Lee—IEEE Trans on Antennas and Propagation, 45(10):1488-1493, October 1997;

Adaptive Integral Methods in “AIM: Adaptative Integral Method for Solving Large Scale Electromagnetic Scattering And Radiation Problems” by E. Bleszynski, M. Bleszynski, T. Jaroszewicz—Radio Science, 31(5):1225-1251, 1996;

insofar as these documents form an integral part of the description.

The invention extends without difficulty to objects (antennas or targets) comprising dielectric materials. In this case, equivalent electric and magnetic currents are sought on each interface. The interaction matrix between these currents comprises diagonal blocks of the same type as the matrix M described above. A preconditioner for the interaction matrix is therefore obtained by considering the blockwise diagonal matrix, whose blocks are of the type of the matrix Z described above.

1. An electromagnetic simulation algorithm, for determining the electromagnetic wave scattered by a body in a monofrequency situation, from a meshing of said body and from the electromagnetic excitation, characterized in that it comprises at least:
(a) a determination of a matrix M, the so-called interaction matrix, whose coefficients are determined from the meshing of said body;
(b) a determination of a preconditioner Z of the matrix M, this preconditioner being the matrix formulation of the operator J☆ M J where M is the operator associated with M, J the operator vector product with the normal to the surface of said body and J☆ the operator adjoined to J;
(b) a determination of the currents which flow around the surface of said body, through an iterative algorithm of conjugate gradient type using said preconditioner Z, the iterative algorithm making it possible to solve an equation, the so-called boundary integral equation of electromagnetism, written in matrix form in the following manner:
MU=L
where U is a vector which we seek to determine, whose coefficients represent the surface currents, and L is a known vector, whose coefficients represent the electromagnetic excitation;
(c) a determination of the wave scattered by said body, from said surface currents.

2. The electromagnetic simulation algorithm as claimed in claim 1, characterized in that the coefficients of the vector U are expressed in the usual basis of the Raviart-Thomas space.

3. The electromagnetic simulation algorithm as claimed in one of the preceding claims, characterized in that the preconditioner Z is determined implicitly

4. The electromagnetic simulation algorithm as claimed in one of the preceding claims, characterized in that the preconditioner Z is defined by the following relation:
Z=^{t}JMJ
where J is a matrix formulation of the operator J and ^{t}J the transposed matrix of J.

5. The electromagnetic simulation algorithm as claimed in claim 4, characterized in that the matrix J is defined by the following relation:
$$J = ( \begin{matrix}1 & - M6 )\end{matrix} {( \begin{matrix}M1 & 0 \\ 0 & M5\end{matrix} )}^{- 1} ( \begin{matrix}M3 & 0 \\ 0 & M4\end{matrix} ) {( \begin{matrix}M1 & M2 \\ {}^{1} M2 & 0\end{matrix} )}^{- 1} ( \begin{matrix}1 \\ 0\end{matrix} )$$
where
$${M1}_{ij} = {\int }_{A ∈ Γ} {\overline{ϕ}}_{i} ( A ) \cdot {\overline{ϕ}}_{j} ( A ) ⅆ {S}_{A}$$
$${M2}_{ij} = {\int }_{A ∈ Γ} {ψ}_{j} ( A ) d i {v}_{A} ( {\overline{ϕ}}_{i} ) ⅆ {S}_{A}$$
$${M3}_{ij} = {\int }_{A ∈ Γ} ( {\overline{ϕ}}_{j} ( A ) ⋀ \vec{z} ( A ) ) \cdot {\overline{ϕ}}_{i} ( A ) ⅆ {S}_{A}$$
$${M4}_{ij} = {\int }_{A ∈ Γ} {ψ}_{j} ( A ) {θ}_{i} ( A ) ⅆ {S}_{A}$$
$${M5}_{ij} = {\int }_{A ∈ Γ} {θ}_{j} ( A ) {θ}_{i} ( A ) ⅆ {S}_{A}$$
$${M6}_{ij} = {( \overline{r o t} ( {θ}_{j} ) )}_{{ϕ}_{1}}$$
where
\vec{φ}ᵢ is the usual basis of the Raviart-Thomas space;
θi is the basis of the trianglewise affine functions;
ψi is the basis of the trianglewise constant functions;
A a point belonging to the surface Γ of said body;
\vec{z}(A) is a vector with unit norm, normal to the surface of said body at the point A, and oriented outward.

6. The electromagnetic simulation algorithm as claimed in one of the preceding claims, characterized in that the iterative algorithm used is a fast algorithm, of the multilevel multipole method type.

7. The electromagnetic simulation algorithm according to one of claims 1 to 5, characterized in that the iterative algorithm used is a fast algorithm, of the adaptive integral method method type.

8. The electromagnetic simulation algorithm as claimed in one of the preceding claims, characterized in that the body is an antenna for which one seeks to determine an optimal shape, by using the simulation algorithm in an antenna design tool.

9. The electromagnetic simulation algorithm as claimed in one of claims 1 to 7, characterized in that the body is an object of known shape for which one seeks to determine the radar cross section (RCS).
